(19) United States
(12) Patent Application Publication
(10) Pub. No.: US 2026/0013166 A1
(43) Pub. Date: Jan. 8, 2026

(54) BACKSIDE POWER DELIVERY IN DEVICES WITHOUT INNER SPACERS

(71) Applicant: Applied Materials, Inc., Santa Clara, CA (US)

(72) Inventors: Veeraraghavan S. BASKER, Schenectady, NY (US); Kyoung KIM, Santa Clara, CA (US); Gregory COSTRINI, Flanders, NJ (US); Ashish PAL, San Ramon, CA (US); El Mehdi BAZIZI, San Anselmo, CA (US); Benjamin COLOMBEAU, San Jose, CA (US); Balasubramanian PRANATHARTHIHARAN, Santa Clara, CA (US)

(21) Appl. No.: 19/215,986

(22) Filed: May 22, 2025

Related U.S. Application Data
(60) Provisional application No. 63/667,073, filed on Jul. 2, 2024.
(60) Provisional application No. 63/714,451, filed on Oct. 31, 2024.

(51) Int. Cl. H10D 30/01; H01L 21/762; H10D 30/00; H10D 62/10; H10D 62/832; H10D 64/62; H10D 84/01; H10D 84/83

(52) U.S. Cl. CPC H10D 30/0198; H01L 21/76224; H10D 84/0149; H10D 84/0151; H10D 30/501; H10D 62/121; H10D 62/832; H10D 64/62; H10D 84/832

(57) ABSTRACT

A method of forming backside contacts to source/drain (S/D) regions of a semiconductor structure includes removing a substrate selectively to shallow trench isolations (STIs) and the extension regions to form first recesses between the STIs, filling the first recesses with first dielectric material, forming second recesses aligned to the S/D regions through the first dielectric material, and forming backside contacts to the extension regions within the second recesses.

### CROSS-REFERENCE TO RELATED APPLICATIONS

This application claims priority to U.S. Provisional Applications Ser. No. 63/667,073 filed Jul. 2, 2024, Ser. No. 63/714,451 filed Oct. 31, 2024, each of which is herein incorporated by reference in its entirety.

### BACKGROUND

### Field

Embodiments described herein generally relate to semiconductor device fabrication, and more particularly, to forming a semiconductor structure for backside power delivery.

### Description of the Related Art

Traditionally, chips are constructed with transistors on a front side of a silicon wafer and all interconnects that power them and transmit their data signals built above them. One of the key technologies to enable scaling below 3 nm involves delivering of power on a back side of a chip. This backside power delivery eliminates the need to share interconnect resources between signals and power lines on a front side of the chip as power is moved to the back side of the chip. Backside power delivery further eliminates the need for a power delivery track from lower layer front side interconnects, leading to cost savings. Backside power delivery also allows different metal layers to be optimally fabricated, such as wider lines for an operating voltage V_{dd} and a common ground voltage Vₛₛ, and thinner lines to carry signals.

However, backside power delivery creates new challenges, such as patterning electrical contact features isolated from one another by isolation modules on a backside of a chip within tight spaces without impacting performance of transistors on a front side of the chip. In particular, in fabrication of devices with no inner spacers to protect source/drain (S/D) layers, corners of the S/D layers are damaged during etching a silicon (Si) substrate from the back side.

Therefore, there is a need for methods for overcoming such challenges in backside power delivery.

### SUMMARY

Embodiments of the present disclosure provide a method of forming backside contacts to source/drain (S/D) regions of a semiconductor structure. The method includes removing a substrate selectively to shallow trench isolations (STIs) and the S/D regions to form first recesses between the STIs, filling the first recesses with first dielectric material, forming second recesses aligned to the S/D regions through the first dielectric material, and forming the backside contacts to the S/D regions within the second recesses.

Embodiments of the present disclosure also provide a method of forming backside contacts to source/drain (S/D) regions of a semiconductor structure. The method removing placeholders formed within a substrate to form first recesses, forming the backside contacts to the S/D regions within the first recesses, etching the substrate selectively to the S/D regions to form second recesses, and filling the second recesses with first dielectric material.

Embodiments of the present disclosure further provide a method of forming backside contacts to source/drain (S/D) regions of a semiconductor structure. The method includes etching a substrate selectively to the S/D regions to form first recesses, filling the first recess with first dielectric material, removing placeholders formed within the substrate to form second recesses, and forming the backside contacts to the S/D regions within the second recesses.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top view of a multi-chamber processing system, according to one or more embodiments of the present disclosure.

FIG. 2 is an isometric view of a portion of a semiconductor structure that may form a gate-all-around field-effect transistor (GAA FET), according to one or more embodiments of the present structure.

FIGS. 3A and 3B depict a process flow diagram of a method of forming a semiconductor structure for backside power delivery for a gate-all-around field-effect transistor (GAA FET) according to a first embodiment.

FIGS. 4A, 4B, 4C, 4D, 4E, 4F, 4G, 4H, 4I, 4J, 4K, and 4L are isometric views of a portion of a semiconductor structure corresponding to various states of the method of FIGS. 3A and 3B.

FIGS. 5A and 5B depict a process flow diagram of a method of forming a semiconductor structure for backside power delivery for a gate-all-around field-effect transistor (GAA FET) according to a second embodiment.

FIGS. 6A, 6B, 6C, 6D, 6E, 6F, 6G, 6H, 6I, 6J, 6K, and 6L are isometric views of a portion of a semiconductor structure corresponding to various states of the method of FIGS. 5A and 5B.

FIGS. 7A and 7B depict a process flow diagram of a method of forming a semiconductor structure for backside power delivery for a gate-all-around field-effect transistor (GAA FET) according to a second embodiment.

FIGS. 8A, 8B, 8C, 8D, 8E, 8F, 8G, 8H, 8I, 8J, 8K, and 8L are isometric views of a portion of a semiconductor structure corresponding to various states of the method of FIGS. 7A and 7B.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

The embodiments described herein provide methods for forming metal contacts isolated from one another by an inter-layer dielectric (ILD), by replacing portions of a chip with dielectric material, from a backside of the chip, while protecting source/drain (S/D) epitaxial (epi) layers on a front side of the chip. The methods described herein include etching of a silicon (Si) substrate without affecting source/drain (S/D) epitaxial (epi) regions which can be n-type (e.g., Si:P) or p-type (e.g., SiGe:B) in devices with no inner spacers, using a conformal extension region formed of silicon germanium (SiGe).

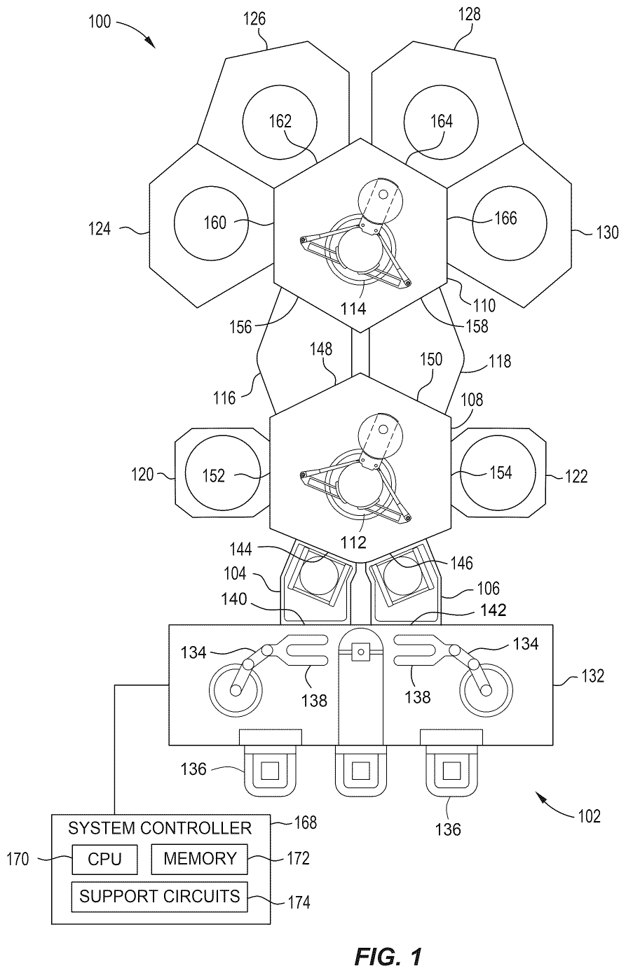

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing etch processes, the processing chamber 122 can be capable of performing cleaning processes, the processing chamber 124 can be capable of performing selective removal processes, the processing chamber 126 can be capable of performing chemical vapor deposition (CVD) deposition processes, and the processing chambers 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126 may be a W×Z™ chamber available from Applied Materials of Santa Clara, Calif. The processing chamber 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

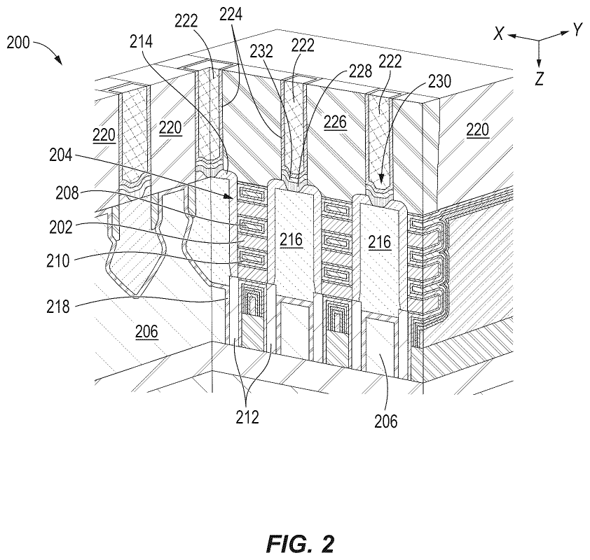

FIG. 2 is an isometric view of a portion of a semiconductor structure 200 that may form a gate-all-around field-effect transistor (GAA FET), according to one or more embodiments of the present structure. A back side of the semiconductor structure 200 is shown upwards in FIG. 2.

As shown in FIG. 2, the semiconductor structure 200 includes channel layers 202 and replacement-metal-gate (RMG) stacks 204, extending in the Y direction, embedded within a front inter-layer dielectric (ILD) 206. Each of the RMG stacks 204 includes a gate metal 208 and a high-k material 210.

The channel layers 202 may be formed of silicon (Si), germanium (Ge), silicon germanium (SiGe), or indium gallium zinc oxide (IGZO). The front ILD 206 may be formed of silicon oxide (SiO₂), silicon oxynitride (SiON), silicon oxy-carbon-nitride (SiOCN), aluminum oxide (Al₂O₃), or any combination thereof. The gate metal 208 may be formed of titanium nitride (TiN), titanium aluminum carbide (TiAlC), or tungsten (W), or may contain other materials such as lanthanum (La), or aluminum (Al). The high-k material 210 may be formed of hafnium oxides (HfO₂), hafnium zirconium oxide (HfZrO₂), and aluminum oxide (Al₂O₃).

Surfaces of the RMG stacks 204 may be covered by spacers 212. The spacers 212 may be formed of dielectric material, such as silicon oxide (SiO₂), silicon oxy-carbide (SiOC), silicon oxy-carbon-nitride (SiOCN), silicon boron carbon nitride (SiBCN), or silicon nitride (Si₃N₄), with a thickness of between about 1 nm and about 8 nm.

The semiconductor structure 200 further includes source/drain (S/D) regions, each of which includes an extension region (also referred to as “L1 layer”) 214 and an S/D epitaxial (epi) layer 216 (also referred to as “L2 layer”) surrounded by the extension region 214, via which the channel layers 202 are electrically connected to a source/drain (S/D) contact (not shown). The S/D epi layer 216 is interfaced with the front ILD 206 via a sacrificial oxide layer 218.

The extension region 214 may be formed of silicon germanium (SiGe) with a ratio of germanium (Ge) ranging between about 5% and about 25%, for example, between about 5.5% and about 6%, lightly doped with p-type dopants such as boron (B) or gallium (Ga), or n-type dopants such as phosphorus (P), arsenic (As), or antimony (Sb), with a concentration of between about 1×10¹⁸ cm⁻³ and 5×10²¹ cm⁻³, depending upon the desired conductive characteristic of the extension regions 214.

The S/D epi layer 216 may be formed of epitaxially grown silicon (Si) doped with p-type dopants such as boron (B) or gallium (Ga), or silicon germanium (SiGe) with a ratio of germanium (Ge) ranging between 35% and 65%, doped with n-type dopants such as phosphorus (P), arsenic (As), or antimony (Sb), with a concentration of between about 1019 cm⁻³ and 5×10²¹ cm⁻³, depending upon the desired conductive characteristic of the S/D epi layer 216.

The semiconductor structure 200 further includes shallow trench isolations (STIs) 220. The STIs 220 may be formed of silicon oxide (SiO₂) or other dielectrics such as silicon nitride (Si₃N₄) silicon boron carbon nitride (SiBCN), silicon oxy-carbon-nitride (SiOCN), silicon oxycarbide (SiOC), organosilicate glass (SiCOH), or any combination thereof. The S/D epi layers 216 are electrically connected to metal fills 222, extending in the Z direction, formed between the STIs 220. The metal fills 222 are each connectable to a voltage source (not shown). The metal fills 222 may be each surrounded by a barrier layer 224. The metal fills 222 on both sides of the channel layers 202 are isolated by a back ILD 226, in addition to the STIs 220.

The metal fills 222 may each have critical dimensions of about 10 nm and about 40 nm in the XY plane and spaced from one another by about 20 nm and about 50 nm. The metal fills 222 may have a depth in the Z direction of between about 10 nm and 100 nm. The metal fills 222 may be formed of tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof. The barrier layer 224 may be formed of titanium nitride (TiN), tantalum nitride (TaN), titanium aluminum carbide (TiAlC), tungsten nitride (WN), or tungsten (W).

The back ILD 226 may be formed of silicon oxide (SiO₂), silicon oxynitride (SiON), aluminum oxide (Al₂O₃), silicon oxy-carbon-nitride (SiOCN), or any combination thereof.

The semiconductor structure 200 further includes a contact epi layer 228 within a cavity 230 formed on a surface of the extension region 214, as an interface between the S/D epi layer 216 and the metal fill 222 via a contact interface 232, to minimize parasitic resistance.

The contact epi layer 228 may be formed of epitaxially grown silicon germanium (SiGe) with a ratio of germanium (Ge) ranging between 25% and 65%, doped with p-type dopants such as boron (B) or gallium (Ga), with a concentration of between about 1×10¹⁸ cm⁻³ and 5×10²¹ cm⁻³, or epitaxially grown silicon (Si), doped with n-type dopants, such as phosphorus (P), arsenic (As), or antimony (Sb), with a concentration of between about 1×10¹⁸ cm⁻³ and 5×10²¹ cm⁻³. The cavity 230 may have a V-shape, a U-shape, or any other shape, and enlarge a contact area of the metal fill 222, to minimize parasitic resistance. The contact interfaces 232 may be formed of metal silicide, such as titanium silicide (TiSi, TiSi₂), nickel silicide (NiSi, Ni₂Si), molybdenum silicide (MoSi, MoSi₂), cobalt silicide (CoSi₂), tantalum silicide (TaSi₂), or any combination thereof.

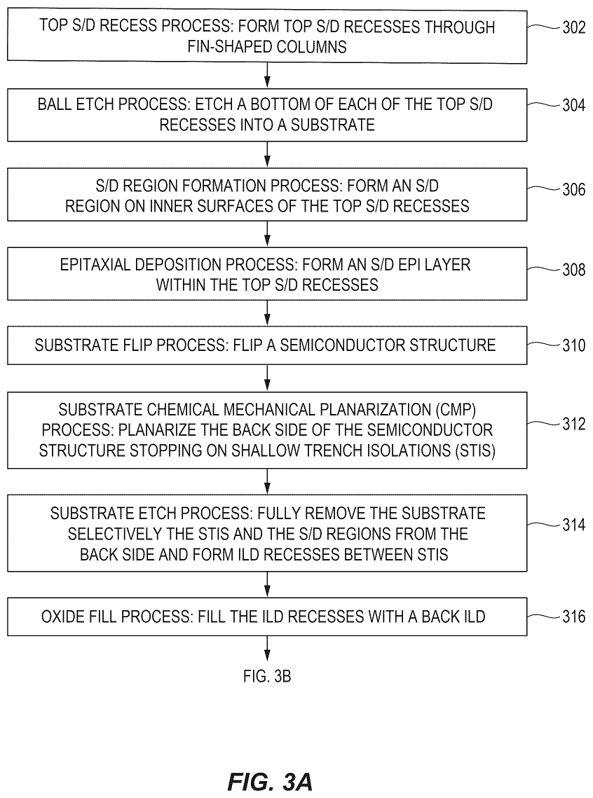

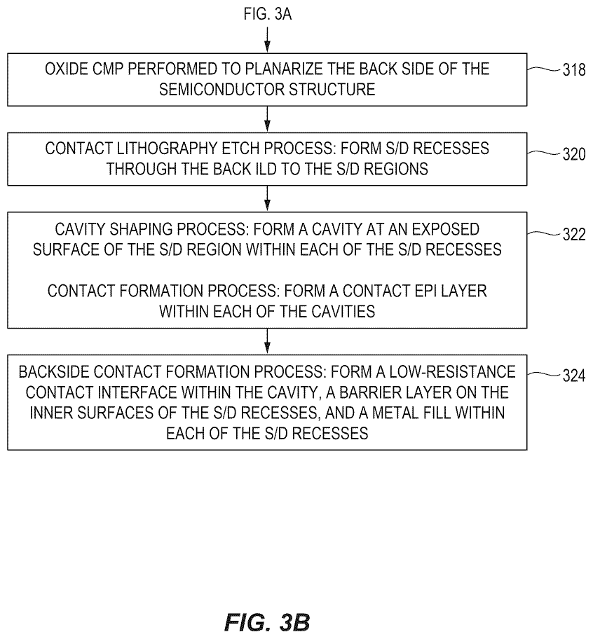

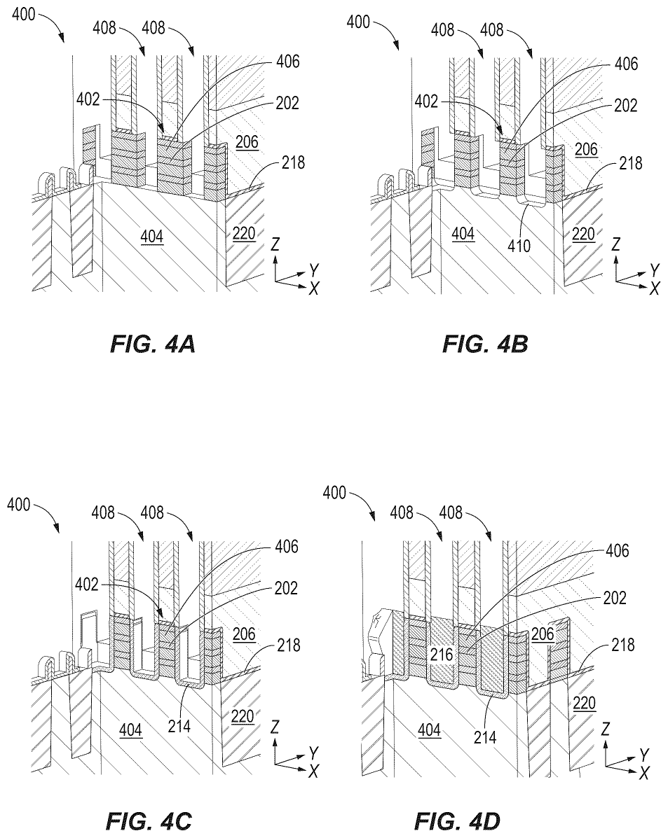

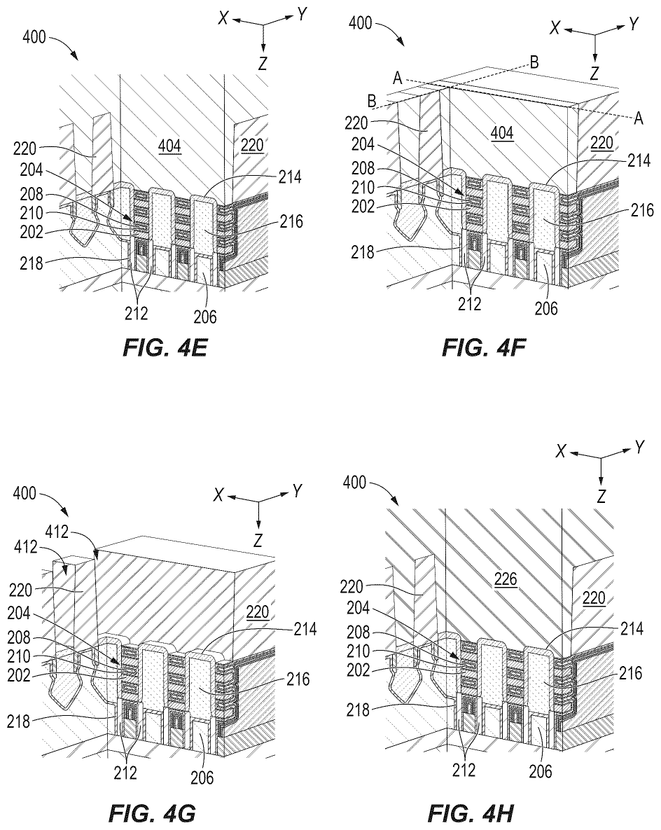

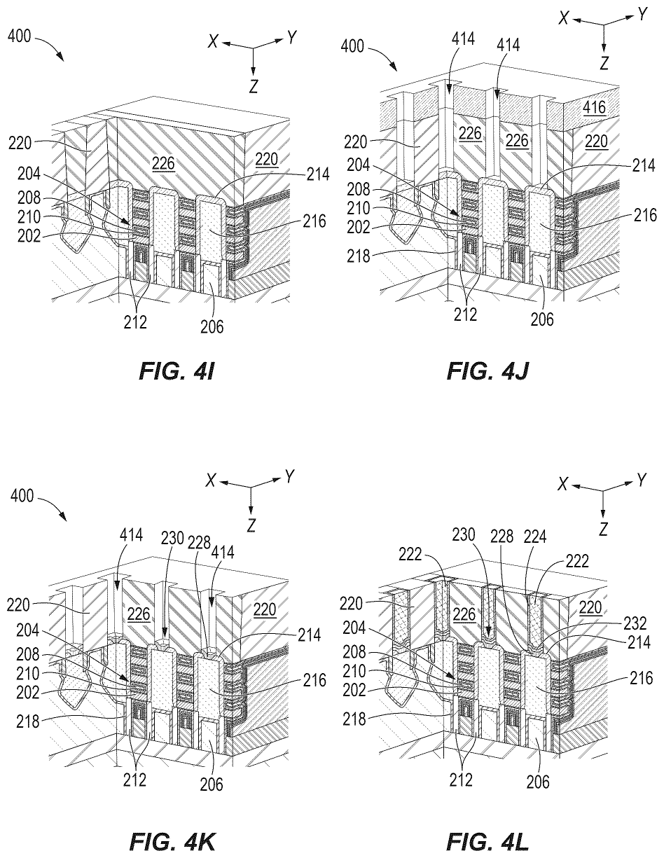

FIGS. 3A and 3B depict a process flow diagram of a method 300 of forming a semiconductor structure 400 that may form a semiconductor structure for backside power delivery for a gate-all-around field-effect transistor (GAA FET), according to a first embodiment of the present disclosure. FIGS. 4A, 4B, 4C, 4D, 4E, 4F, 4G, 4H, 4I, 4J, 4K, and 4L are isometric views of a portion of the semiconductor structure 400, with a cut-out of the semiconductor structure 400 along the YZ plane including the line A-A (shown in FIG. 4F) and a cut-out of the semiconductor structure 400 along the ZX plane including the line B-B (shown in FIG. 4F), corresponding to various states of the method 300. It should be understood that FIGS. 4A, 4B, 4C, 4D, 4E, 4F, 4G, 4H, 4I, 4J, 4K, and 4L illustrate only partial schematic views of the semiconductor structure 400, and the semiconductor structure 400 may contain any number of transistor sections and additional materials having aspects as illustrated in the figures. It should also be noted that although the method illustrated in FIGS. 3A and 3B is described sequentially, other process sequences that include one or more operations that have been omitted and/or added, and/or has been rearranged in another desirable order, fall within the scope of the embodiments of the disclosure provided herein.

As shown in FIG. 4A, the semiconductor structure 400 includes fin-shaped columns 402 formed on a substrate 404. The substrate 404 is patterned and shallow trench isolations (STIs) 220 are formed within the substrate 404. The fin-shaped columns 402 extend in the X direction and are isolated from adjacent fin-shaped columns 402 in the Y direction by a front inter-layer dielectric (ILD) 206. The fin-shaped columns 402 each include a stack of alternating channel layers 202 and sacrificial layers 406 in the Z direction. The fin-shaped columns 402 may be formed by epitaxially growing the stack of alternating channel layers 202 and sacrificial layers 406 on the substrate 404, and patterning the stack of alternating channel layers 202 and sacrificial layers 406. The STI 220 is formed around the fin-shaped columns 402 and a sacrificial oxide layer 218 is deposited over the fin-shaped columns and STI 220. Dummy gates are formed over the fin-shaped columns 402. The sacrificial layers 406 are to be replaced with RMG stacks 204.

The term “substrate” as used herein refers to a layer of material that serves as a basis for subsequent processing operations and includes a surface to be cleaned. The substrate may be a silicon-based material or any suitable insulating materials or conductive materials as needed. The substrate may include a material such as crystalline silicon (e.g., Si<100>, Si<110>, or Si<111>), silicon oxide, strained silicon, silicon germanium, doped or undoped polycrystalline silicon, doped or undoped silicon wafers and patterned or non-patterned wafers, silicon on insulator (SOI), carbon doped silicon oxides, silicon nitride, doped silicon, germanium, gallium arsenide, glass, or sapphire.

The method 300 begins with block 302, in which a top S/D recess process is performed to form top S/D recesses 408 through the fin-shaped columns 402, as shown in FIG. 4A.

The top S/D recess process may include any appropriate lithography and etch processes, such as photolithography and dry anisotropic etching, performed in a processing chamber, such as the processing chamber 120 shown in FIG. 1.

In block 304, a bottom etch process is performed to etch a bottom 410 of each of the top S/D recesses 408 into the substrate 404, as shown in FIG. 4B.

The bottom etch process may include an anisotropic remote plasma assisted dry etch process, such as a reactive ion etching (RIE) process, in a processing chamber, such as the processing chamber 124 shown in FIG. 1, using a plasma formed from a gas including argon (Ar), helium (He), nitrogen (N₂), or a combination thereof. The plasma effluents directionally bombard and isotropically etch the bottom 410 of each of the top S/D recesses 408. In some embodiments, the bottom 410 of each of the top S/D recesses 408 is etched by between about 1 nm and about 8 nm, for example, about 5 nm.

In block 306, an extension region formation process is performed to form an extension region (also referred to as “L1 layer”) 214 on inner surfaces of the top S/D recesses 408, as shown in FIG. 4C. The extension region 214 will be used as an etch stop layer in the subsequent substrate removal process in block 314. The extension region 214 may be formed by an epitaxial deposition process, performed in a processing chamber, such as the processing chamber 126, 128, or 130 shown in FIG. 1.

The extension region 214 may be formed of silicon germanium (SiGe) with a ratio of germanium (Ge) ranging between about 5% and about 25%, for example, between about 5.5% and about 6%, lightly doped with p-type dopants such as boron (B) or gallium (Ga), or n-type dopants such as phosphorus (P), arsenic (As), or antimony (Sb), with a concentration of between about 1×10¹⁸ cm⁻³ and 5×10²¹ cm⁻³, depending upon the desired conductive characteristic of the extension regions 214.

In block 308, an epitaxial deposition process is performed to form an S/D epi layer 216 within the top S/D recesses 408, as shown in FIG. 4D. The epitaxial deposition process is performed in a processing chamber, such as the processing chamber 126, 128, or 130 shown in FIG. 1. Since the extension region 214 (e.g., silicon germanium (SiGe)) seals comers of the bottom 410 of each of the top S/D recesses 408, and has etch selectivity from the substrate 404 (e.g., silicon (Si)), the S/D epi layer 216 within the top S/D recesses 408 is protected during the subsequent substrate removal process in block 312, in which the substrate 404 is etched from a back side (the side of the substrate 404).

In block 310, a substrate flip process is performed to flip the semiconductor structure 400 such that the semiconductor structure 400 is to be processed from the back side (the side of the substrate 404), as shown in FIG. 4E.

In block 312, a substrate chemical mechanical planarization (CMP) process is performed to planarize the back side of the semiconductor structure 400 stopping on shallow trench isolations (STIs) 220, as shown in FIG. 4F.

In block 314, a substrate removal process is performed to remove the substrate 404 selectively to the STIs 220 and the extension regions 214 from the back side of the semiconductor structure 400 and form ILD recesses 412 between STIs 220, as shown in FIG. 4G. The substrate removal process may include any wet etch process, performed in a processing chamber, such as the processing chamber 120 shown in FIG. 1.

The extension region 214 (e.g., silicon germanium (SiGe) with low germanium (Ge) ratio) has etch selectivity from the substrate 404 and covers the S/D epi layer 216 including the top corners of the S/D epi layer 216. Thus, the extension region 214 acts as an etch stop layer and the S/D epi layer 216 is protected during the substrate removal process.

In block 316, an oxide fill process is performed to fill the ILD recesses 412 with a back ILD 226, as shown in FIG. 4H. The back ILD 226 may be formed of silicon oxide (SiO₂), silicon oxynitride (SiON), aluminum oxide (Al₂O₃), silicon oxy-carbon-nitride (SiOCN), or any combination thereof. The oxide fill process may include a deposition process, such as chemical vapor deposition (CVD), physical vapor deposition (PVD), or the like performed in a processing chamber, such as the processing chamber 126, 128, or 130 shown in FIG. 1. The oxide fill process may be performed at a low temperature of between about 150° C. and about 400° C.

In block 318, an oxide CMP process is performed to planarize the back side of the semiconductor structure 400, as shown in FIG. 4I.

In block 320, a contact lithography etch process is performed to form bottom S/D recesses 414 aligned to the extension regions 214 through the back ILD 226, as shown in FIG. 4J. The contact lithography etch process may be any appropriate lithography and etch processes, using a mask 416, such as photolithography and dry anisotropic etching, performed in a processing chamber, such as the processing chamber 120 shown in FIG. 1. In some embodiments, a dielectric liner (not shown) may be formed on inner surfaces of the bottom S/D recesses 414. The dielectric liner may be formed of silicon nitride (Si₃N₄), silicon oxide (SiO₂), silicon oxynitride (SiON), aluminum oxide (Al₂O₃), silicon oxy-carbon-nitride (SiOCN), or any combination thereof, having a thickness of between about 1 nm and about 10 nm, for example, about 4 nm.

In block 322, a cavity shaping process is performed to form a cavity 230 at an exposed surface of the extension region 214 within each of the bottom S/D recesses 414, and a contact formation process is performed to form a contact epi layer 228 within each of the cavities 230, as shown in FIG. 4K.

The cavity 230 may have a V-shape, a U-shape, or any other shape, and enlarge a contact area of a metal fill to be formed within the bottom S/D recess 414, to minimize parasitic resistance.

The cavity shaping process to form the cavity 230 includes an etch process using an etching gas including halogen-containing gas, such as chlorine (Cl₂), hydrogen chloride (HCl), or hydrogen fluoride (HF), carbon-containing fluorine (F) chemistries, such as tetrafluoromethane (CF₄), trifluoromethane (CHF₃), difluoromethane (CH₂F₂), or fluoromethane (CH₃F), bromine-containing chemistries such as HBr, and carrier gas, such as argon (Ar), or helium (He), performed in an etch chamber, such as the processing chamber 120 shown in FIG. 1.

The contact epi layer 228 is formed as an interface between the S/D epi layer 216 and a metal fill to be formed within the bottom S/D recess 414, to minimize parasitic resistance. The contact epi layer 228 is formed of silicon germanium (SiGe) with a ratio of germanium (Ge) ranging between 25% and 65%, doped with p-type dopants such as boron (B) or gallium (Ga), with a concentration of between about 1×10¹⁸ cm⁻³ and 5×10²¹ cm⁻³, or epitaxially grown silicon (Si), doped with n-type dopants, such as phosphorus (P), arsenic (As), or antimony (Sb), with a concentration of between about 1×10¹⁸ cm⁻³ and 5×10²¹ cm⁻³.

In block 324, a backside contact formation process is performed to form a backside contact to the extension region 214, including a low-resistance contact interface 232 within the cavity 230, a barrier layer 224 on the inner surfaces of the bottom S/D recesses 414, and a metal fill 222 within each of the bottom S/D recesses 414, as shown in FIG. 4L.

The contact interface 232 provides an electrical connection between the extension region 214 and the metal fill 222.

In some embodiments, the contact interface 232 is formed of molybdenum (Mo), ruthenium (Ru), or silicide thereof, formed on the extension region 214 of p-type. In the deposition process, a deposition gas including a metal source, such as a molybdenum (Mo)-containing halide precursor, or a ruthenium (Ru)-containing organometallic that includes ruthenium (Ru), is used. A silicide forming process to form the contact interface 232 includes a deposition process, such as chemical vapor deposition (CVD), physical vapor deposition (PVD), or the like performed in a processing chamber, such as the processing chamber 126, 128, or 130 shown in FIG. 1, at a temperature of between about 240° C. and about 450° C. and at a pressure of between 3 Torr and 300 Torr. During the deposition process, argon (Ar) gas may be supplied at a flow rate of between about 0 sccm and about 1000 sccm, and hydrogen (H₂) gas may be supplied at a flow rate of between about 500 sccm and about 15000 sccm, for example.

In some embodiments, the contact interface 232 is formed of a second metal material, such as titanium (Ti), cobalt (Co), nickel (Ni), tantalum (Ta), lanthanum (La), yttrium (Y), hafnium (Hf), zirconium (Zr), or silicide thereof, formed on the extension region 214 of n-type. In the deposition process, a deposition gas including a metal source, such as a precursor containing titanium (Ti), tantalum (Ta), cobalt (Co), nickel (Ni), or a combination thereof. The deposition process may be performed at a temperature of between about 300° C. and about 800° C. and at a pressure of between 1° Torr and 50° Torr.

A cycle of the silicide forming process may be repeated as needed to obtain a desired thickness of the contact interface 232, for example, between about 5 times and about 1000 times.

The barrier layer 224 may be formed of titanium nitride (TiN), tantalum nitride (TaN), titanium aluminum carbide (TiAlC), tungsten nitride (WN), or tungsten (W). A deposition process to form the barrier layer 224 may include any appropriate deposition process, such as chemical vapor deposition (CVD), or physical vapor deposition (PVD).

The metal fill 222 may be formed of contact metal material, such as tungsten (W), cobalt (Co), ruthenium (Ru), or molybdenum (Mo). The metal fill 222 may include a metal that has a desirable work function. A contact metallization process to form the metal fill 222 may include a chemical vapor deposition (CVD) process using a tungsten-containing precursor, such as WF₆, or a cobalt-containing precursor, in a processing chamber, such as the processing chamber 126, 128, or 130 shown in FIG. 1. After the metal filling process, the semiconductor structure 400 may be planarized to arrive the semiconductor structure 200, as shown in FIG. 2.

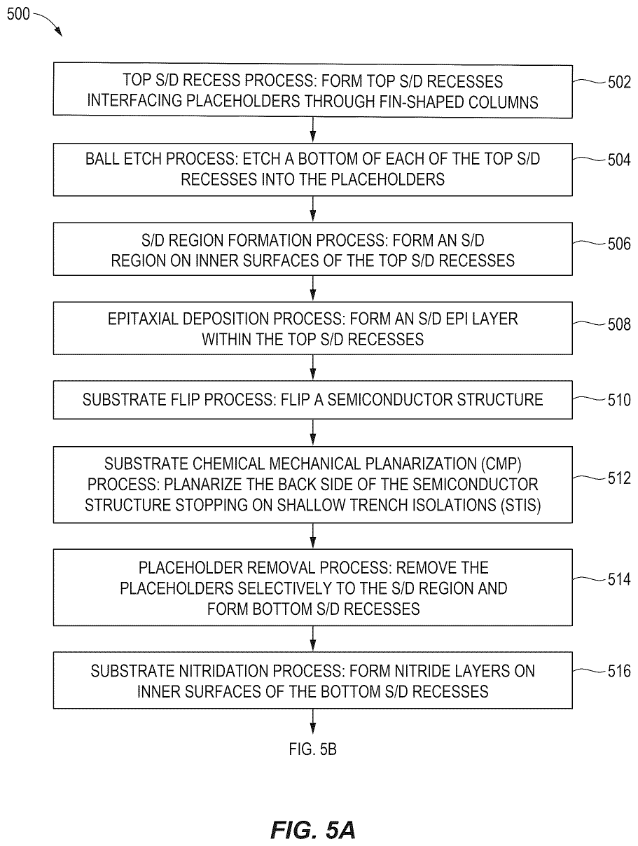

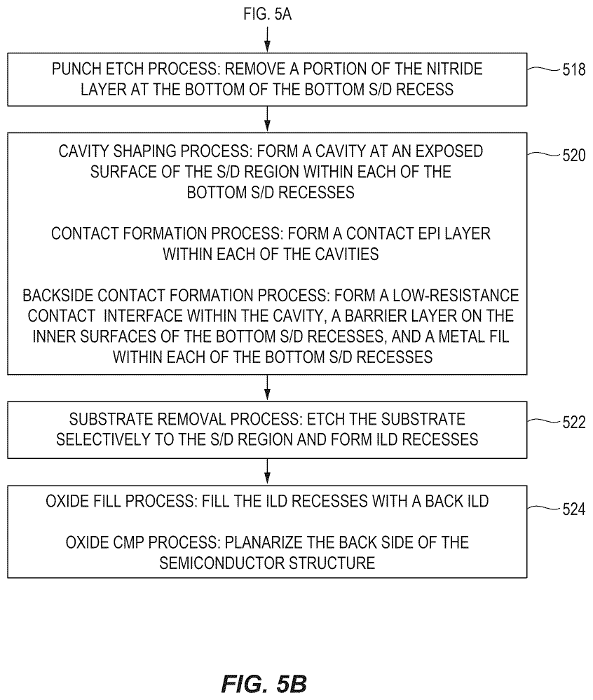

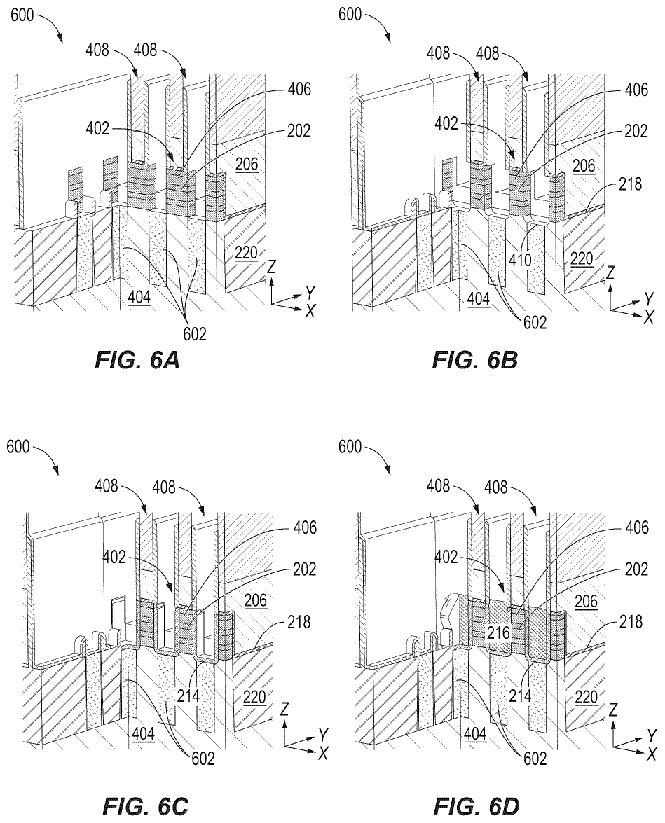

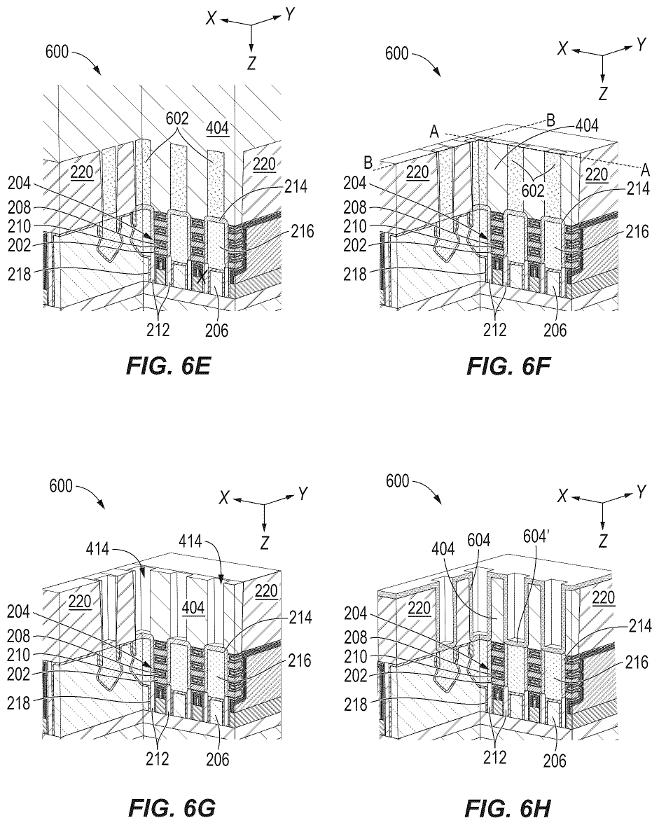

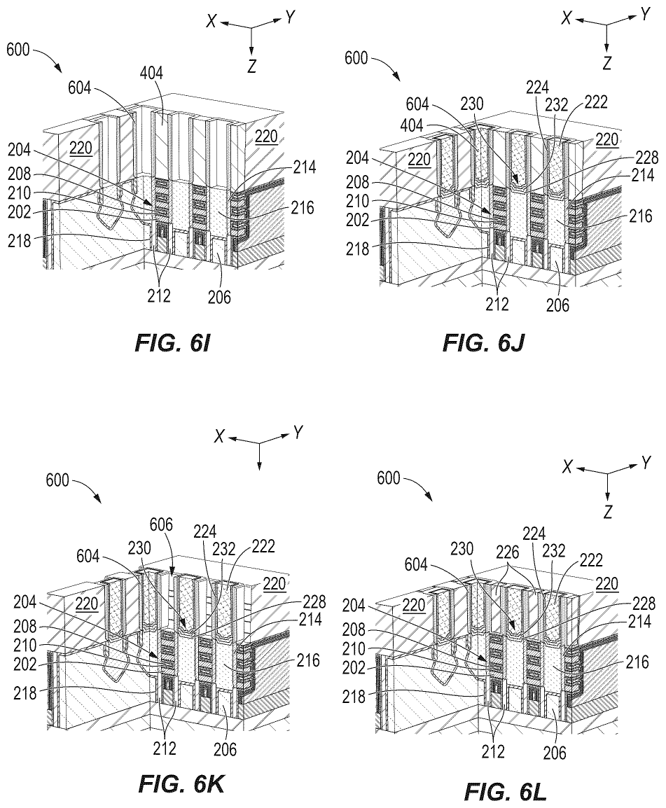

FIGS. 5A and 5B depict a process flow diagram of a method 500 of forming a semiconductor structure 600 that may form a semiconductor structure for backside power delivery for a gate-all-around field-effect transistor (GAA FET), according to a second embodiment of the present disclosure. FIGS. 6A, 6B, 6C, 6D, 6E, 6F, 6G, 6H, 6I, 6J, 6K, and 6L are isometric views of a portion of the semiconductor structure 600, with a cut-out of the semiconductor structure 600 along the YZ plane including the line A-A (shown in FIG. 6F) and a cut-out of the semiconductor structure 600 along the ZX plane including the line B-B (shown in FIG. 6F), corresponding to various states of the method 500. It should be understood that FIGS. 6A, 6B, 6C, 6D, 6E, 6F, 6G, 6H, 6I, 6J, 6K, and 6L illustrate only partial schematic views of the semiconductor structure 600, and the semiconductor structure 600 may contain any number of transistor sections and additional materials having aspects as illustrated in the figures. It should also be noted that although the method illustrated in FIGS. 5A and 5B is described sequentially, other process sequences that include one or more operations that have been omitted and/or added, and/or has been rearranged in another desirable order, fall within the scope of the embodiments of the disclosure provided herein.

As shown in FIG. 6A, the semiconductor structure 600 includes fin-shaped columns 402 formed on a substrate 404. The substrate 404 is patterned and shallow trench isolations (STIs) 220 are formed within the substrate 404. The fin-shaped columns 402 extend in the X direction and are isolated from adjacent fin-shaped columns 402 in the Y direction by a front inter-layer dielectric (ILD) 206. The fin-shaped columns 402 each include a stack of alternating channel layers 202 and sacrificial layers 406 in the Z direction. The fin-shaped columns 402 may be formed by epitaxially growing the stack of alternating channel layers 202 and sacrificial layers 406 on the substrate 404, and patterning the stack of alternating channel layers 202 and sacrificial layers 406. The STI 220 is formed around the fin-shaped columns and a sacrificial oxide layer 218 is deposited over the fin-shaped columns and STI 220. Dummy gates are formed over the fin-shaped columns 402. The sacrificial layers 406 are to be replaced with RMG stacks 204.

Within the substrate 404, placeholders 602 are formed and isolated by the STIs 220. The placeholders 602 are formed of silicon germanium (SiGe) with a ratio of germanium (Ge) ranging between about 15% and about 50%, or metal such as titanium nitride (TiN), using any appropriate deposition process, such as chemical vapor deposition (CVD), or physical vapor deposition (PVD), performed in a processing chamber, such as the processing chamber 126, 128, or 130 shown in FIG. 1.

The method 500 begins with block 502, in which a top S/D recess process is performed to form top S/D recesses 408 interfacing the placeholders 602, through the fin-shaped columns 402, as shown in FIG. 6A. The top S/D recess process in block 502 may be the same as the S/D recess process in block 302.

In block 504, a bottom etch process is performed to etch a bottom 410 of each of the top S/D recesses 408 into the placeholders 602, as shown in FIG. 6B. The bottom etch process in block 504 may be the same as the bottom etch process in block 304.

In block 506, an extension region formation process is performed to form an extension region (also referred to as “L1 layer”) 214 on inner surfaces of the top S/D recesses 408, as shown in FIG. 6C. The extension region 214 will be used as an etch stop layer in the subsequent placeholder removal process in block 514 and the substrate removal process in block 522. The extension region formation process in block 506 may be the same as the extension region formation process in block 306.

In block 508, an epitaxial deposition process is performed to form an S/D epi layer 216 within the top S/D recesses 408, as shown in FIG. 6D. The epitaxial deposition process in block 508 may be the same as the epitaxial deposition process in block 308.

In block 510, a substrate flip process is performed to flip the semiconductor structure 600 such that the semiconductor structure 600 is to be processed from the back side (the side of the substrate 404), as shown in FIG. 6E.

In block 512, a substrate chemical mechanical planarization (CMP) process is performed to planarize the back side of the semiconductor structure 600 stopping on shallow trench isolations (STIs) 220, as shown in FIG. 6F.

In block 514, a placeholder removal process is performed to remove the placeholders 602 (e.g., silicon germanium (SiGe) with high germanium (Ge) ratio, or metal such as titanium nitride (TiN)) selectively to the extension region 214 (e.g., silicon germanium (SiGe) with low germanium (Ge) ratio) and form bottom S/D recesses 414, as shown in FIG. 6G. The extension region 214 (e.g., silicon germanium (SiGe) with low germanium (Ge) ratio) has etch selectivity from the placeholders 602 (e.g., silicon germanium (SiGe) with high germanium (Ge) ratio, or metal such as titanium nitride (TiN)), and thus acts as an etch stop layer during the placeholder removal process.

The placeholder removal process may include any appropriate dry anisotropic etching or wet etching process, performed in a processing chamber, such as the processing chamber 120 shown in FIG. 1.

In block 516, a substrate nitridation process is performed to form nitride layers 604 on inner surfaces of the bottom S/D recesses 414, as shown in FIG. 6H.

The nitride layers 604 may be formed of silicon nitride (Si₃N₄) having a thickness of between about 1 nm and about 8 nm, for example, about 5 nm.

The substrate nitridation process may be a plasma treatment process, such as a decoupled plasma nitridation (DPN) process, a decoupled plasma (DPX) process, a decoupled plasma plus (DPX+) process, or a rapid thermal nitridation (RTN) process performed in a processing chamber, such as a Radiance™ chamber, available from Applied Materials, Inc., Santa Clara, Calif. or the processing chambers 120, 122, 124, 126, 128, and 130 shown in FIG. 1. Gases that may be used in the plasma treatment process include nitrogen containing gas, such as nitrogen (N₂), ammonia (NH₃), or mixtures thereof.

In block 518, a punch etch process is performed to remove a portion 604′ of the nitride layer 604 at the bottom of the bottom S/D recess 414, as shown in FIG. 6I.

The punch etch process may include an anisotropic remote plasma assisted dry etch process, such as a reactive ion etching (RIE) process, in a processing chamber, such as the processing chamber 124 shown in FIG. 1, using a plasma formed from a gas including argon (Ar), helium (He), nitrogen (N₂), or a combination thereof. The plasma effluents directionally bombard and remove the portion 604′ of the nitride layer 604 at the bottom of the bottom S/D recess 414.

The nitride layers 604 on sidewalls of the bottom S/D recesses 414 remain un-etched.

In block 520, a cavity shaping process is performed to form a cavity 230 at an exposed surface of the extension region 214 within each of the bottom S/D recesses 414, a contact formation process is performed to form a contact epi layer 228 within each of the cavities 230, and a backside contact-formation process is performed to form a low-resistance contact interface 232 within the cavity 230, a barrier layer 224 on the inner surfaces of the bottom S/D recesses 414, and a metal fill 222 within each of the bottom S/D recesses 414, as shown in FIG. 6J. The cavity shaping process and the contact formation process in block 520 may be the same as the cavity shaping process in block 322 and the silicide forming process in block 324.

In block 522, a substrate removal process is performed to etch the substrate 404 (e.g., silicon (Si)) selectively to the extension region 214 (e.g., silicon germanium (SiGe)) and form ILD recesses 606, as shown in FIG. 6K.

The nitride layers 604 may protect the extension region 214 during the substrate removal process.

The substrate removal process may include any appropriate wet isotropic etching process, performed in a processing chamber, such as the processing chamber 120 shown in FIG. 1.

The extension region 214 (e.g., silicon germanium (SiGe) with low germanium (Ge) ratio) has etch selectivity from the substrate 404, and acts as an etch stop layer during the substrate removal process.

In block 524, an oxide fill process is performed to fill the ILD recesses 606 with a back ILD 226 and an oxide CMP process is performed to planarize the back side of the semiconductor structure 600, as shown in FIG. 6L. The oxide fill process in block 524 may be the same as the oxide fill process in block 316.

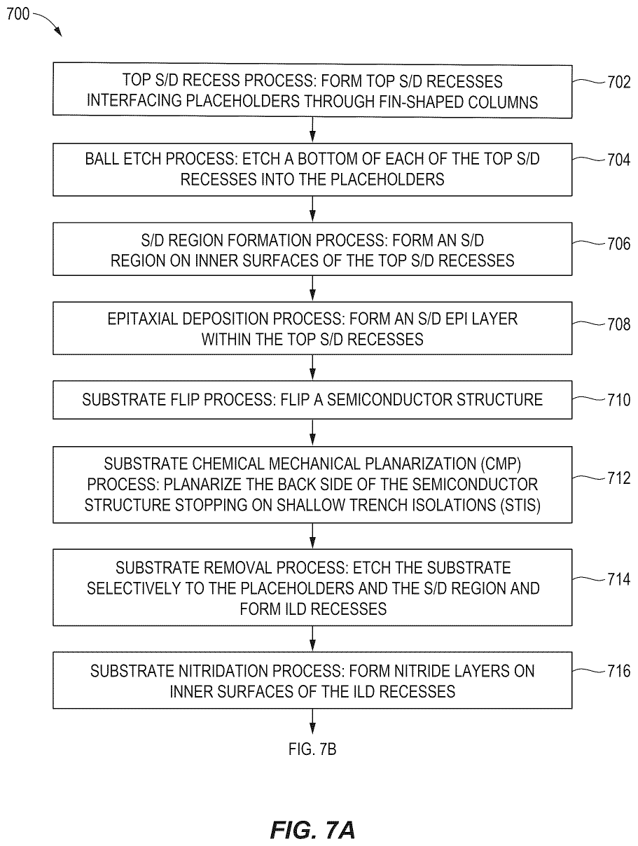

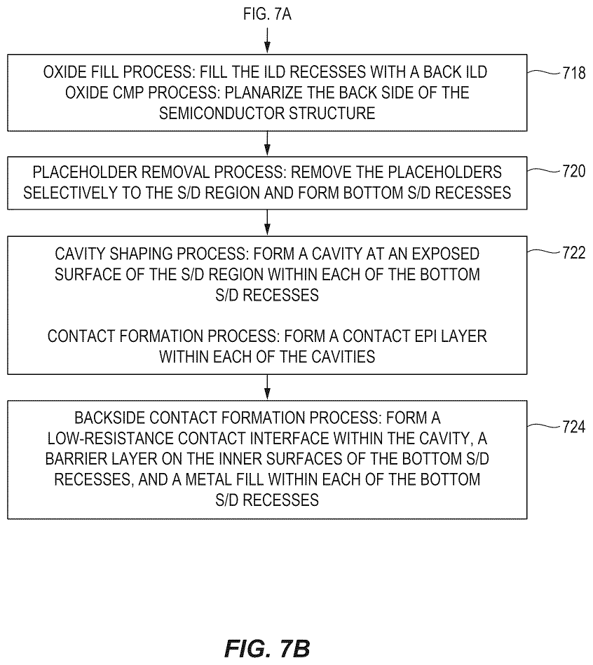

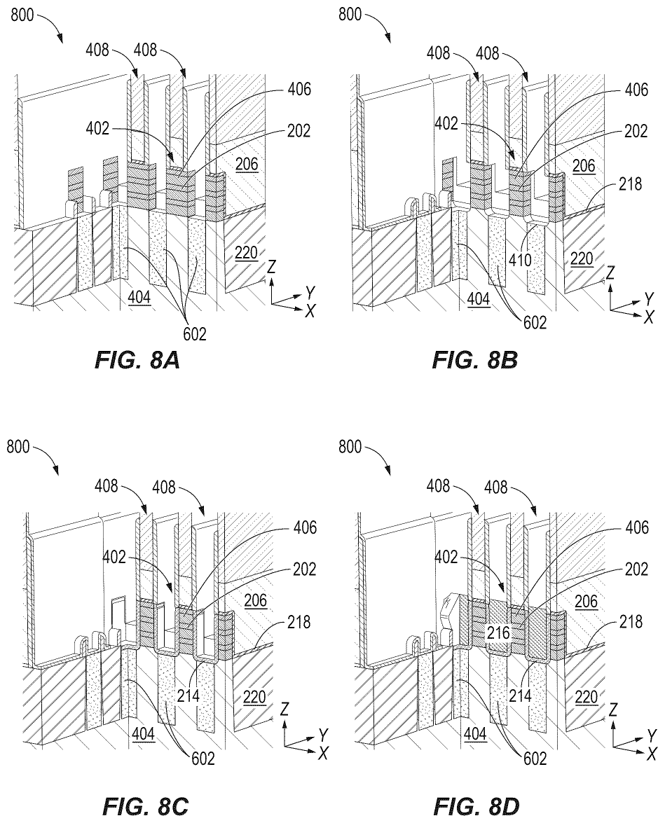

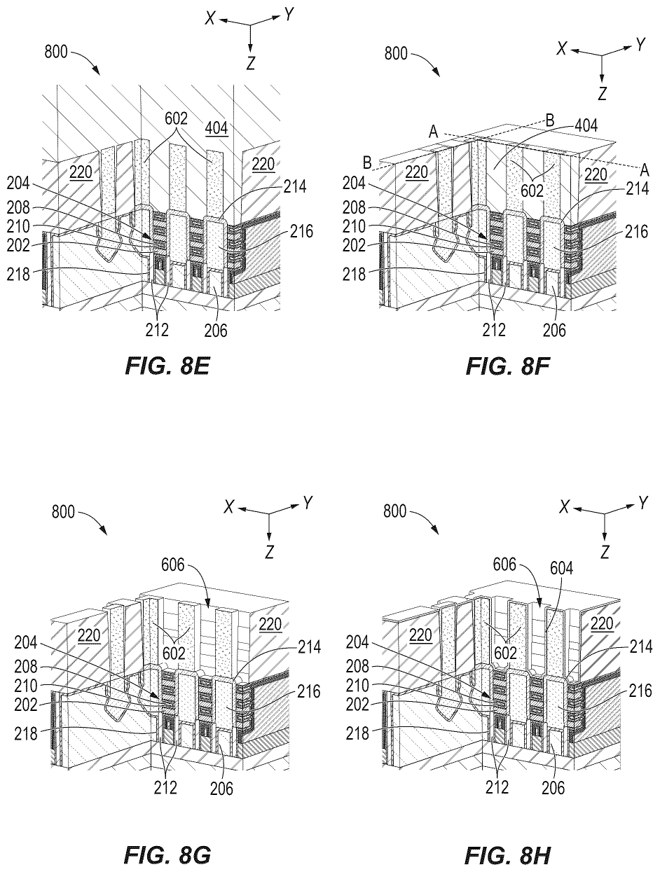

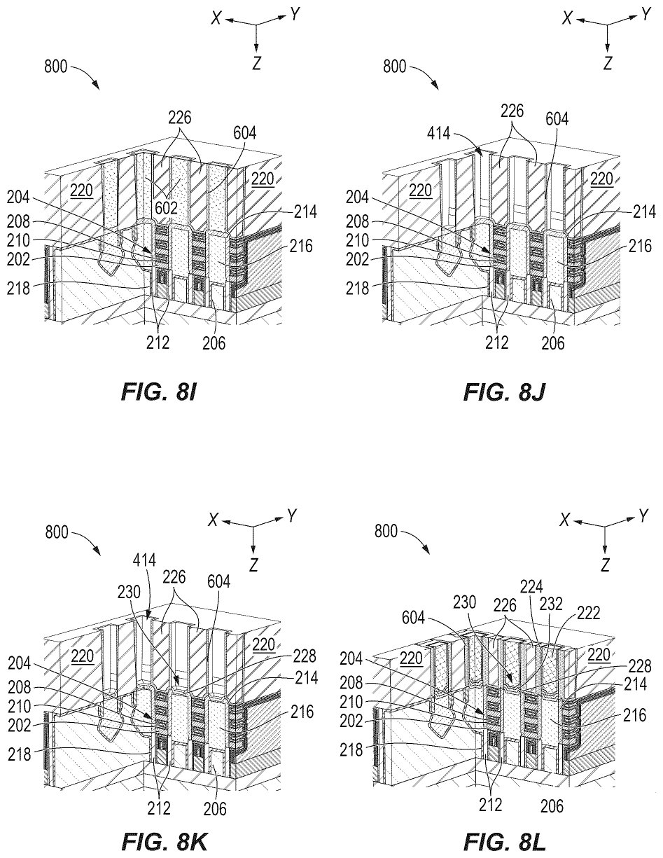

FIGS. 7A and 7B depict a process flow diagram of a method 700 of forming a semiconductor structure 800 that may form a semiconductor structure for backside power delivery for a gate-all-around field-effect transistor (GAA FET), according to a second embodiment of the present disclosure. FIGS. 8A, 8B, 8C, 8D, 8E, 6F, 8G, 8H, 8I, 8J, 8K, and 8L are isometric views of a portion of the semiconductor structure 800, with a cut-out of the semiconductor structure 800 along the YZ plane including the line A-A (shown in FIG. 8F) and a cut-out of the semiconductor structure 800 along the ZX plane including the line B-B (shown in FIG. 8F), corresponding to various states of the method 700. It should be understood that FIGS. 8A, 8B, 8C, 8D, 8E, 8F, 8G, 8H, 8I, 8J, 8K, and 8L illustrate only partial schematic views of the semiconductor structure 800, and the semiconductor structure 800 may contain any number of transistor sections and additional materials having aspects as illustrated in the figures. It should also be noted that although the method illustrated in FIGS. 7A and 7B is described sequentially, other process sequences that include one or more operations that have been omitted and/or added, and/or has been rearranged in another desirable order, fall within the scope of the embodiments of the disclosure provided herein.

As shown in FIG. 8A, the semiconductor structure 800 includes fin-shaped columns 402 formed on a substrate 404. The substrate 404 is patterned and shallow trench isolations (STIs) 220 are formed within the substrate 404. The fin-shaped columns 402 extend in the X direction and are isolated from adjacent fin-shaped columns 402 in the Y direction by a front inter-layer dielectric (ILD) 206. The fin-shaped columns 402 each include a stack of alternating channel layers 202 and sacrificial layers 406 in the Z direction. The fin-shaped columns 402 may be formed by epitaxially growing the stack of alternating channel layers 202 and sacrificial layers 406 on the substrate 404, and patterning the stack of alternating channel layers 202 and sacrificial layers 406. The STI 220 is formed around the fin-shaped columns and a sacrificial oxide layer 218 is deposited over the fin-shaped columns and STI 220. Dummy gates are formed over the fin-shaped columns 402. The sacrificial layers 406 are to be replaced with RMG stacks 204.

Within the substrate 404, placeholders 602 are formed and isolated by the STIs 220. The placeholders 602 are formed of silicon germanium (SiGe) with a ratio of germanium (Ge) ranging between about 15% and about 50%, or metal such as titanium nitride (TiN), using any appropriate deposition process, such as chemical vapor deposition (CVD), or physical vapor deposition (PVD), performed in a processing chamber, such as the processing chamber 126, 128, or 130 shown in FIG. 1.

The method 700 begins with block 702, in which a top S/D recess process is performed to form top S/D recesses 408 interfacing the placeholders 602, through the fin-shaped columns 402, as shown in FIG. 8A. The top S/D recess process in block 702 may be the same as the S/D recess process in block 302.

In block 704, a bottom etch process is performed to etch a bottom 410 of each of the top S/D recesses 408 into the placeholders 602, as shown in FIG. 8B. The bottom etch process in block 704 may be the same as the bottom etch process in block 304.

In block 706, an extension region formation process is performed to form an extension region (also referred to as “L1 layer”) 214 on inner surfaces of the top S/D recesses 408, as shown in FIG. 8C. The extension region 214 will be used as an etch stop layer in the subsequent substrate removal process in block 714 and the placeholder removal process in block 720. The extension region formation process in block 706 may be the same as the extension region formation process in block 306.

In block 708, an epitaxial deposition process is performed to form an S/D epi layer 216 within the top S/D recesses 408, as shown in FIG. 8D. The epitaxial deposition process in block 708 may be the same as the epitaxial deposition process in block 308.

In block 710, a substrate flip process is performed to flip the semiconductor structure 800 such that the semiconductor structure 800 is to be processed from the back side (the side of the substrate 404), as shown in FIG. 8E.

In block 712, a substrate chemical mechanical planarization (CMP) process is performed to planarize the back side of the semiconductor structure 800 stopping on shallow trench isolations (STIs) 220, as shown in FIG. 8F.

In block 714, a substrate removal process is performed to etch the substrate 404 (e.g., silicon (Si)) selectively to the placeholders 602 (e.g., silicon germanium (SiGe)) and the extension region 214 (e.g., silicon germanium (SiGe)) and form ILD recesses 606, as shown in FIG. 8G.

The substrate removal process may include any appropriate wet isotropic etching process, performed in a processing chamber, such as the processing chamber 120 shown in FIG. 1.

The extension region 214 (e.g., silicon germanium (SiGe) with low germanium (Ge) ratio) has etch selectivity from the substrate 404 and covers the S/D epi layer 216 including the top corners of the S/D epi layer 216. Thus, the extension region 214 acts as an etch stop layer and the S/D epi layer 216 is protected during the substrate removal process.

In block 716, a substrate nitridation process is performed to form nitride layers 604 on inner surfaces of the ILD recesses 606, as shown in FIG. 8H.

The nitride layers 604 may be formed of silicon nitride (Si₃N₄) having a thickness of between about 1 nm and about 8 nm, for example, about 3 nm.

The substrate nitridation process may be a plasma treatment process, such as a decoupled plasma nitridation (DPN) process, a decoupled plasma (DPX) process, a decoupled plasma plus (DPX+) process, or a rapid thermal nitridation (RTN) process performed in a processing chamber, such as a Radiance™ chamber, available from Applied Materials, Inc., Santa Clara, Calif. or the processing chambers 120, 122, 124, 126, 128, and 130 shown in FIG. 1. Gases that may be used in the plasma treatment process include nitrogen containing gas, such as nitrogen (N₂), ammonia (NH₃), or mixtures thereof.

In block 718, an oxide fill process is performed to fill the ILD recesses 606 with a back ILD 226 and a CMP process is performed to planarize the back side of the semiconductor structure 800, as shown in FIG. 8I. The oxide fill process in block 718 may be the same as the oxide fill process in block 316.

In block 720, a placeholder removal process is performed to remove the placeholders 602 (e.g., silicon germanium (SiGe) with high germanium (Ge) ratio, or metal such as titanium nitride (TiN)) selectively to the extension region 214 (e.g., silicon germanium (SiGe) with low germanium (Ge) ratio) and form bottom S/D recesses 414, as shown in FIG. 8J. The extension region 214 (e.g., silicon germanium (SiGe) with low germanium (Ge) ratio) has etch selectivity from the placeholders 602 (e.g., silicon germanium (SiGe) with high germanium (Ge) ratio, or metal such as titanium nitride (TiN)), and thus acts as an etch stop layer during the placeholder removal process.

The placeholder removal process may include any appropriate dry anisotropic etching or wet etching process, performed in a processing chamber, such as the processing chamber 120 shown in FIG. 1.

In block 722, a cavity shaping process is performed to form a cavity 230 at an exposed surface of the extension region 214 within each of the bottom S/D recesses 414, a contact formation process is performed to form a contact epi layer 228 within each of the cavities 230, as shown in FIG. 8K.

The cavity shaping process in block 722 may be the same as the cavity shaping process in block 322.

In block 724, a backside contact formation process is performed to form a low-resistance contact interface 232 within the cavity 230, a barrier layer 224 on the inner surfaces of the bottom S/D recesses 414, and a metal fill 222 within each of the bottom S/D recesses 414, as shown in FIG. 8J. The cavity shaping process and the contact formation process in block 720 may be the same as the cavity shaping process in block 322 and the silicide forming process in block 324. Further, a CMP process is performed to planarize the back side of the semiconductor structure 800.

The embodiments described herein provide methods for forming metal contacts isolated from one another by an inter-layer dielectric (ILD), by replacing portions of a chip with dielectric material, from a backside of the chip, while protecting source/drain (S/D) epitaxial (epi) layers on a front side of the chip. The methods described herein etch a silicon (Si) substrate without affecting source/drain (S/D) epitaxial (epi) regions which can be n-type (e.g., Si:P) or p-type (e.g., SiGe:B) in devices with no inner spacers, using a conformal extension region formed of silicon germanium (SiGe).

It should be noted that the methods described herein can be applied to devices other than gate-all-around field-effect transistor (GAA FET) devices, such forksheet transistor devices and complementary field-effect transistor (CFET) devices.

While the foregoing is directed to embodiments of the present disclosure, other and further embodiments of the disclosure may be devised without departing from the basic scope thereof, and the scope thereof is determined by the claims that follow.

1. A method of forming backside contacts to source/drain (S/D) regions of a semiconductor structure, comprising:
removing a substrate selectively to shallow trench isolations (STIs) and the S/D regions to form first recesses between the STIs;
filling the first recesses with first dielectric material;
forming second recesses aligned to the S/D regions through the first dielectric material; and
forming the backside contacts to the S/D regions within the second recesses.

2. The method of claim 1, wherein:
each of the S/D regions comprises an S/D epi layer and an extension region that surrounds the S/D epi layer, and
the extension regions each comprise silicon germanium (SiGe) with a ratio of germanium (Ge) ranging between 5% and 25%.

3. The method of claim 2, further comprising:
etching a bottom of each of first recesses formed through fin-shaped columns on the substrate;
forming the extension regions on inner surfaces of the first recesses; and
forming the S/D epi layers within the first recesses.

4. The method of claim 3, wherein:
each of the fin-shaped columns comprises a stack of alternating channel layers and sacrificial layers,
the STIs comprise silicon oxide (SiO₂), and
the first dielectric material comprises silicon oxide (SiO₂), silicon oxynitride (SiON), aluminum oxide, or (Al₂O₃).

5. The method of claim 1, wherein forming the backside contacts comprises:
forming a cavity at an exposed surface of the S/D region within each of the second recesses;
forming a contact epi layer with each of the cavities; and
forming a contact interface within each of the cavities, a barrier layer on inner surfaces of the second recesses, and a metal fill within each of the second recesses.

6. The method of claim 5, wherein:
the contact epi layer comprises epitaxially grown silicon germanium (SiGe),
the contact interface comprises molybdenum silicide (MoSi, MoSi₂), titanium silicide (TiSi, TiSi₂), cobalt silicide (CoSi₂), or nickel silicide (NiSi, Ni₂Si),
the barrier layer comprises titanium nitride (TiN), tantalum nitride (TaN), titanium aluminum carbide (TiAlC), tungsten nitride (WN), or tungsten (W), and
the metal fill comprises tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof.

7. A method of forming backside contacts to source/drain (S/D) regions of a semiconductor structure, comprising:
removing placeholders formed within a substrate to form first recesses;
forming the backside contacts to the S/D regions within the first recesses;
etching the substrate selectively to the S/D regions to form second recesses; and
filling the second recesses with first dielectric material.

8. The method of claim 7, wherein:
each of the S/D regions comprises an S/D epi layer and an extension region that surrounds the S/D epi layer,
the extension regions each comprise silicon germanium (SiGe) with a ratio of germanium (Ge) ranging between 5% and 25%, and
the placeholders comprise silicon germanium (SiGe) with a ratio of germanium (Ge) ranging between 15% and 50% or titanium nitride (TIN).

9. The method of claim 8, further comprising:
etching a bottom of each of third recesses formed through fin-shaped columns on the substrate;
forming the extension regions on inner surfaces of the third recesses; and
forming the S/D epi layers within the third recesses.

10. The method of claim 9, wherein:
each of the fin-shaped columns comprises a stack of alternating channel layers and sacrificial layers,
the STIs comprise silicon oxide (SiO₂), and
the first dielectric material comprises silicon oxide (SiO₂), silicon oxynitride (SiON), aluminum oxide, or (Al₂O₃).

11. The method of claim 7, further comprising:
forming nitride layers on inner surfaces of the first recesses; and
removing portions of the nitride layers at bottoms of the first recesses.

12. The method of claim 7, wherein forming the backside contacts comprises:
forming a cavity at an exposed surface of extension region within each of the first recesses;
forming a contact epi layer within each of the cavities; and
forming a contact interface within each of the cavities, a barrier layer on inner surfaces of the first recesses, and a metal fill within each of the first recesses.

13. The method of claim 12, wherein:
the contact epi layer comprises epitaxially grown silicon germanium (SiGe),
the contact interface comprises molybdenum silicide (MoSi, MoSi₂), titanium silicide (TiSi, TiSi₂), cobalt silicide (CoSi₂), or nickel silicide (NiSi, Ni₂Si),
the barrier layer comprises titanium nitride (TiN), tantalum nitride (TaN), titanium aluminum carbide (TiAlC), tungsten nitride (WN), or tungsten (W), and
the metal fill comprises tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof.

14. A method of forming backside contacts to source/drain (S/D) regions of a semiconductor structure, comprising:
etching a substrate selectively to the S/D regions to form first recesses;
filling the first recesses with first dielectric material;
removing placeholders formed within the substrate to form second recesses; and
forming the backside contacts to the S/D regions within the second recesses.

15. The method of claim 14, wherein:
each of the S/D regions comprises an S/D epi layer and an extension region that surrounds the S/D epi layer,
the extension regions each comprise silicon germanium (SiGe) with a ratio of germanium (Ge) ranging between 5% and 25%, and
the placeholders comprise silicon germanium (SiGe) with a ratio of germanium (Ge) ranging between 15% and 50% or titanium nitride (TiN).

16. The method of claim 15, further comprising:
etching a bottom of each of third recesses formed through fin-shaped columns on the substrate;
forming the extension regions on inner surfaces of the third recesses; and
forming S/D epi layers within the third recesses.

17. The method of claim 16, wherein:
each of the fin-shaped columns comprises a stack of alternating channel layers and sacrificial layers,
the STIs comprise silicon oxide (SiO₂), and
the first dielectric material comprises silicon oxide (SiO₂), silicon oxynitride (SiON), aluminum oxide, or (Al₂O₃).

18. The method of claim 14, further comprising:
forming nitride layers on inner surfaces of the first recesses; and
removing portions of the nitride layers at bottoms of the first recesses.

19. The method of claim 14, wherein forming the backside contacts comprises:
forming a cavity at an exposed surface of extension region within each of the first recesses;
forming a contact epi layer within each of the cavities; and
forming a contact interface within each of the cavities, a barrier layer on inner surfaces of the first recesses, and a metal fill within each of the first recesses.

20. The method of claim 19, wherein:
the contact epi layer comprises epitaxially grown silicon germanium (SiGe),
the contact interface comprises molybdenum silicide (MoSi, MoSi₂), titanium silicide (TiSi, TiSi₂), cobalt silicide (CoSi₂), or nickel silicide (NiSi, Ni₂Si),
the barrier layer comprises titanium nitride (TiN), tantalum nitride (TaN), titanium aluminum carbide (TiAlC), tungsten nitride (WN), or tungsten (W), and
the metal fill comprises tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof.
